(19) United States
(12) Patent Application Publication
(10) Pub. No.: US 2005/0178578 A1
(43) Pub. Date: Aug. 18, 2005

(54) High voltage cable

(76) Inventor: Brian E. Gorrell, Fremont, IN (US)

Correspondence Address: BARNES & THORNBURG, 11 SOUTH MERIDIAN, INDIANAPOLIS, IN, 46204, US

(21) Appl. No.: 11/102,399

(22) Filed: Apr. 8, 2005

Related U.S. Application Data
(63) Continuation of application No. 09/982,154, filed on Oct. 18, 2001, now abandoned.
(60) Provisional application No. 60/298,254, filed on Jun. 14, 2001.

(51) Int. Cl. H02G 3/04; H01B 5/08; H01L 21/336

(52) U.S. Cl. 174/98; 174/128.1; 174/68.1

(57) ABSTRACT

A high voltage cable includes a fiber core, a first layer of electrically relatively non-insulative polymer, a second layer of electrically relatively non-conductive polymer, a third layer of electrically relatively non-insulative polymer, a fourth layer including a braided wire shield, and a fifth layer including a solvent- and abrasion-resistant polymer jacket.

### CROSS-REFERENCE TO RELATED APPLICATIONS

This is a regular utility patent application which claims priority to U.S. provisional patent application Ser. No. 60/298,254, filed Jun. 14, 2001, and assigned to the same assignee as this application. The disclosure of 60/298,254 is hereby incorporated herein by reference.

### FIELD OF THE INVENTION

This invention relates to devices for coupling power supplies to devices for utilizing the output of such power supplies. It relates particularly to high magnitude potential supplies of the type which supply operating potential to devices for the electrostatically aided atomization and dispensing of coating materials of various types.

### BACKGROUND OF THE INVENTION

There are a number of known constructions for cables of various types. There are, for example, the cable constructions illustrated and described in U.S. Pat. Nos.: 6,180,888; 6,005,191; 5,998,736; 5,656,796; 5,558,794; 5,523,534; 5,521,009; 5,473,113; 5,414,211; 5,166,477; 4,739,935; 4,576,827; 4,130,450; and, 3,792,409. The disclosures of these references are hereby incorporated herein by reference. No representation is intended by this listing that this is a complete listing of all pertinent prior art, or that a thorough search of all pertinent prior art has been conducted, or that no better prior art exists. Nor should any such representation be inferred.

### DISCLOSURE OF THE INVENTION

According to one aspect of the invention, a high voltage cable includes a fiber core, a first layer of electrically relatively non-insulative polymer, a second layer of electrically relatively non-conductive polymer, a third layer of electrically relatively non-insulative polymer, a fourth layer including a braided wire shield, and a fifth layer including a solvent- and abrasion-resistant polymer jacket.

Illustratively according to this aspect of the invention, the fiber core includes a stranded fiber polyester core.

Further illustratively according to this aspect of the invention, the fiber core is impregnated to increase its bulk conductivity.

Additionally illustratively according to this aspect of the invention, the fiber core is impregnated with carbon black.

Illustratively according to this aspect of the invention, the first layer includes a layer of semiconductive polyethylene.

Further illustratively according to this aspect of the invention, the layer of semiconductive polyethylene includes a layer of carbon black-loaded polyethylene.

Illustratively according to this aspect of the invention, the second layer includes a layer of electrically non-conductive polyethylene.

Further illustratively according to this aspect of the invention, the layer of electrically non-conductive polyethylene includes a layer of relatively high molecular weight, relatively low density polyethylene.

Illustratively according to this aspect of the invention, the third layer includes a layer of electrically relatively non-insulative polyvinyl chloride.

Further illustratively according to this aspect of the invention, the layer of electrically relatively non-insulative polyvinyl chloride includes a layer of spirally extruded electrically relatively non-insulative polyvinyl chloride.

Illustratively according to this aspect of the invention, the metal braid shield contains copper. Alternatively or additionally illustratively, the metal braid shield contains tin.

Further illustratively according to this aspect of the invention, the metal braid of the metal braid shield covers between about 85% and about 100% of the outside surface of the third layer.

Additionally illustratively according to this aspect of the invention, the pitch of the braid of the metal braid shield is less than or equal to about 20° to a perpendicular to the longitudinal extent of the cable.

Illustratively according to this aspect of the invention, the polymer jacket includes a flexible polyurethane jacket.

According to another aspect of the invention, a combination includes a high magnitude electrostatic potential supply, a device for the electrostatically aided atomization and dispensing of a coating material, a source of the coating material coupled to the device, and a high voltage cable coupling the potential supply to the device. The high voltage cable includes a fiber core, a first layer of electrically relatively non-insulative polymer, a second layer of electrically relatively non-conductive polymer, a third layer of electrically relatively non-insulative polymer, a fourth layer including a braided wire shield, and a fifth layer including a solvent- and abrasion-resistant polymer jacket.

### BRIEF DESCRIPTION OF THE DRAWINGS

The invention may best be understood by referring to the following detailed description of an illustrative embodiment of the invention, and the accompanying drawings which illustrate the invention. In the drawings:

FIG. 1 illustrates a block diagram of a system incorporating a cable constructed according to the invention; and,

FIG. 2 illustrates a perspective view of a cable constructed according to the invention, with the various layers of the cable peeled back to expose other layers underneath.

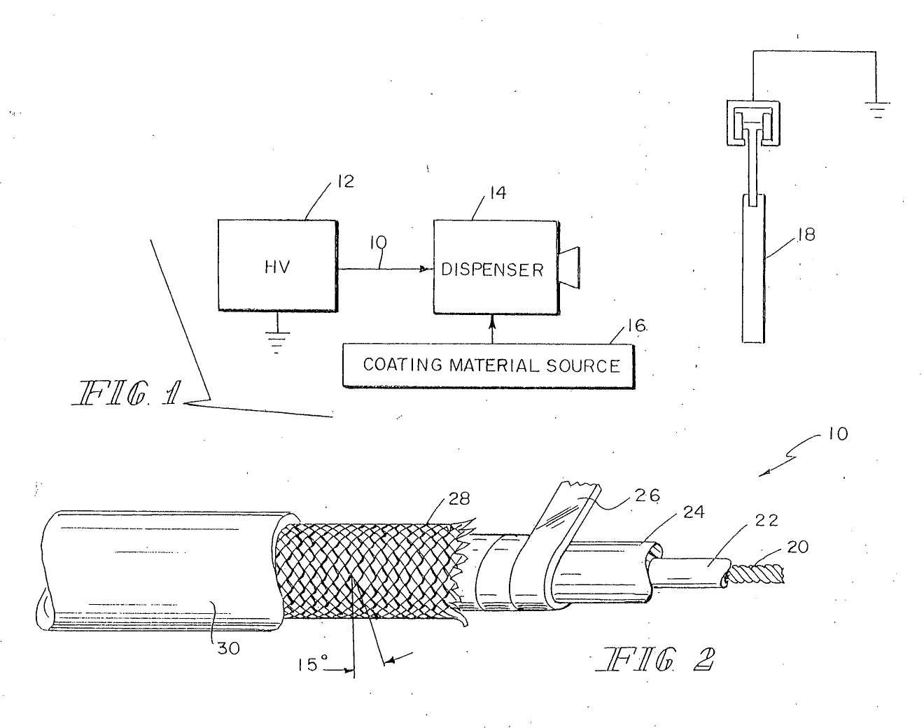

### DETAILED DESCRIPTION OF AN ILLUSTRATIVE EMBODIMENT

As used in this application, terms such as “electrically conductive” and “electrically non-insulative” refer to a broad range of conductivities electrically more conductive than materials described as “electrically non-conductive” and “electrically insulative.” Terms such as “electrically semiconductive” refer to a broad range of conductivities between electrically conductive and electrically non-conductive.

A high voltage cable 10 couples a high magnitude electrostatic potential supply 12 of the general type described in, for example, U.S. Pat. Nos. 3,851,618; 3,875,892; 3,894,272; 4,075,677; 4,187,527; 4,324,812; 4,481,557; 4,485,427; 4,745,520; 5,159,544; and, 5,978,244, to a device 14 for the electrostatically aided atomization and dispensing of a coating material 16 onto articles 18 to be coated by the coating material 16. Many such devices 14 for atomizing and dispensing many different types of materials 16 are known in the art. The disclosures of U.S. Pat. Nos.: 3,851,618; 3,875,892; 3,894,272; 4,075,677; 4,187,527; 4,324,812; 4,481,557; 4,485,427; 4,745,520; 5,159,544; and, 5,978,244 are also hereby incorporated herein by reference.

Cable 10 includes a fiber core 20, illustratively, a 1500 NEA stranded fiber polyester cord. The fiber core 20 can be impregnated, or doped, with, for example, carbon black. Alternatively, it may be undoped. Doping the fiber core 20 with conductive material to make the fiber core 20 conductive or semiconductive permits reduction of its overall cross-section, increases flexibility of the high voltage cable 10, and permits the application of more dielectric material around the fiber core 20 for the same cross sectional area of cable 10. The increase in the amount of dielectric material in turn reduces voltage stress.

The fiber core 20 is covered by a thickness 22 of, for example, 0.030″±0.001″, of electrically non-insulative polymer such as, for example, Union Carbide DHDA-7707 Black 55 carbon black-loaded polyethylene resin semiconductive material. Next, a thickness 24 of, for example, 0.230″±0.007″, of electrically non-conductive polyethylene such as, for example, Union Carbide DFD-6005 Natural high molecular weight, low density polyethylene, is applied over the electrically non-insulative sheath 22.

Next, a thickness 26 of, for example, 0.015″, of spirally extruded electrically non-insulative polyvinyl chloride is applied over the polyethylene core 24. Next, a tin-copper braid shield 28 having, for example, 95% coverage, is applied over the polyvinyl chloride 26. The pitch of the weave of the braid 28 is, for example, 15 degrees from a diameter of the cable 10 (75 degrees measured from an axis of the cable 10), see FIG. 2, making the weave tighter, with greater coverage. The more tightly woven, higher pitch braid 28 reduces the likelihood of breakage or other failure of the braid 28 because of the reduction in the movement of the braid 28 as the cable 10 is flexed, and because of the more uniform containment of the portion of the cable 10 interior to braid 28, since the material interior to braid 28 is less apt to be extruded into the voids in the braid 28, because these voids in the braid 28 are smaller. The wire braid 28 is illustratively formed from 34 AWG tin-coated copper wire. The braid 28 also provides a ground which extends over the length of the cable 10.

Finally, an outer protective, solvent- and abrasive-resistant, yet flexible polyurethane jacket 30 covers the rest of the assembly. The jacket 30 may be constructed from, for example, B. F. Goodrich Company Chemical Group Estane 58092 compound.

An illustrative high voltage cable 10 constructed in this manner has a calculated impedance of 80Ω, a calculated inductance of about 0.14 μH/ft. (about 46 μH/m), a calculated capacitance of about 19 pF/ft. (about 62 pF/m), a calculated propagation velocity of about 0.66c, a calculated center conductor (20, where fiber core 20 is electrically non-insulative,) 22 DC resistance of about 66.84 MΩ/1000 ft. (about 220 KΩ/m), and a calculated braid 28 DC resistance of about 2.5Ω/1000 ft. (about 0.008Ω/m).

1. A high voltage cable including a fiber core, a first layer of an electrically relatively non-insulative polymer, a second layer of an electrically relatively non-conductive polymer, a third layer of an electrically relatively non-insulative polymer, a fourth layer including a metal braid shield, and a fifth layer including a relatively solvent- and abrasive-resistant polymer jacket.

2. The cable of claim 1 wherein the fiber core includes a stranded fiber polyester core.

3. The cable of claim 2 wherein the fiber core is impregnated to increase its bulk conductivity.

4. The cable of claim 3 wherein the fiber core is impregnated with carbon black.

5. The cable of claim 1 wherein the fiber core is impregnated to increase its bulk conductivity.

6. The cable of claim 5 wherein the fiber core is impregnated with carbon black.

7. The cable of claim 1 wherein the first layer includes a layer of semiconductive polyethylene.

8. The cable of claim 7 wherein the layer of semiconductive polyethylene includes a layer of carbon black-loaded polyethylene.

9. The cable of claim 1 wherein the second layer includes a layer of electrically relatively non-conductive polyethylene.

10. The cable of claim 9 wherein the layer of electrically relatively non-conductive polyethylene includes a layer of relatively high molecular weight, relatively low density polyethylene.

11. The cable of claim 1 wherein the third layer includes a layer of electrically relatively non-insulative polyvinyl chloride.

12. The cable of claim 11 wherein the layer of electrically relatively non-insulative polyvinyl chloride includes a layer of spirally extruded electrically relatively non-insulative polyvinyl chloride.

13. The cable of claim 1 wherein the third layer includes a layer of spirally extruded electrically relatively non-insulative polymer.

14. The cable of claim 1 wherein the metal braid shield includes a copper-containing braid shield.

15. The cable of claim 14 wherein the copper-containing braid shield further contains tin.

16. The cable of claim 1 wherein the metal braid shield includes a tin-containing braid shield.

17. The cable of claim 1 wherein the metal braid shield includes a metal braid covering between about 85% and about 100% of the outside surface of the third layer of electrically relatively non-insulative polymer.

18. The cable of claim 1 wherein the pitch of the braid of the metal braid shield is between about 0° and about 20° to a perpendicular to the longitudinal extent of the cable.

19. The cable of claim 1 wherein the polymer jacket includes a flexible polyurethane jacket.

20. The cable of claim 1 in combination with a high magnitude electrostatic potential supply, a device for the electrostatically aided atomization and dispensing of a coating material, a source of the coating material coupled to the device, the high voltage cable coupling the potential supply to the device.
